(19) United States
(12) Patent Application Publication
(10) Pub. No.: US 2026/0150445 A1
(43) Pub. Date: May 28, 2026

(54) DISPLAY PANEL, DISPLAY APPARATUS, AND METHOD FOR MANUFACTURING DISPLAY PANEL

(71) Applicants: Hefei Visionox Technology Co., Ltd., Hefei (CN); Visionox Technology Inc., Kunshan (CN)

(72) Inventors: Zongzhi CHEN, Hefei (CN); Wenyu ZENG, Hefei (CN); Qinggang LIU, Hefei (CN); Xiangqian WANG, Kunshan (CN); Yicheng HU, Hefei (CN); Hao JI, Kunshan (CN)

(73) Assignees: Hefei Visionox Technology Co., Ltd., Hefei (CN); Visionox Technology Inc., Kunshan (CN)

(21) Appl. No.: 19/396,247

(22) Filed: Nov. 20, 2025

(30) Foreign Application Priority Data
Nov. 26, 2024 (CN) 202411709486.6

(51) Int. Cl. H10H 20/853; H10H 20/01; H10H 29/01; H10H 29/37

(52) U.S. Cl. CPC H10H 20/853; H10H 20/0362; H10H 29/012; H10H 29/37

(57) ABSTRACT

Embodiments of the present application provide a display panel, a display apparatus, and a method for manufacturing a display panel. The display panel includes: a substrate, an isolation structure, a light-emitting layer, and a first encapsulation layer. The isolation structure is disposed on a side of the substrate and encloses an isolation opening, the isolation opening including a first isolation opening and a second isolation opening. The light-emitting layer includes a light-emitting unit at least partially located within the isolation opening. The first encapsulation layer includes an encapsulation portion configured to encapsulate each light-emitting unit, the encapsulation portion including a first high-density layer and a low-density layer that are stacked, and the encapsulation portion including a first encapsulation portion located within the first isolation opening and a second encapsulation portion located within the second isolation opening.

### CROSS-REFERENCE TO RELATED APPLICATIONS

The present application claims priority to the Chinese Patent Application NO. 202411709486.6, filed on Nov. 26, 2024, and the entire contents of the aforementioned application are hereby incorporated by reference in its entirety.

### FIELD

The present application relates to the field of display devices, and particularly to a display panel, a display apparatus, and a method for manufacturing a display panel.

### BACKGROUND

Organic light-emitting diodes (OLEDs) and flat panel display apparatuses based on technologies such as light-emitting diodes (LEDs) have been widely used in various consumer electronics such as mobile phones, televisions, notebook computers, and desktop computers, and predominate in display apparatuses thanks to their advantages such as high image quality, energy efficiency, slim design, and a wide range of applications.

However, the usage performance of conventional display products needs to be improved.

### SUMMARY

Embodiments of the present application provide a display panel, a display apparatus, and a method for manufacturing a display panel, with a view to improving the usage performance of the display panel.

An embodiment of the present application provides a display panel. The display panel includes: a substrate, an isolation structure, a light-emitting layer, and a first encapsulation layer, where the isolation structure is disposed on a side of the substrate and encloses an isolation opening, the isolation opening including a first isolation opening and a second isolation opening; the light-emitting layer includes a light-emitting unit at least partially located within the isolation opening; and the first encapsulation layer includes an encapsulation portion configured to encapsulate each light-emitting unit, the encapsulation portion including a first high-density layer and a low-density layer that are stacked, and the encapsulation portion including a first encapsulation portion located within the first isolation opening and a second encapsulation portion located within the second isolation opening, where a film thickness of the low-density layer of at least one first encapsulation portion is less than a film thickness of the low-density layer of the second encapsulation portion.

In an embodiment according to the present application, the isolation structure includes a first sub-layer and a second sub-layer, the second sub-layer being located on a side of the first sub-layer that faces away from the substrate, and an orthographic projection of the first sub-layer on the substrate being within an orthographic projection of the second sub-layer on the substrate.

In an embodiment according to the present application, on a peripheral side of the first isolation opening, there is a first spacing between an edge of the orthographic projection of the first sub-layer on the substrate and an edge of the orthographic projection of the second sub-layer on the substrate; and on a peripheral side of the second isolation opening, there is a second spacing between an edge of the orthographic projection of the first sub-layer on the substrate and an edge of the orthographic projection of the second sub-layer on the substrate, the first spacing being less than or equal to the second spacing.

In an embodiment according to the present application, on the peripheral side of the first isolation opening, there is the first spacing between an edge of an orthographic projection, on the substrate, of a surface of the first sub-layer that faces the second sub-layer and the edge of the orthographic projection of the second sub-layer on the substrate.

In an embodiment according to the present application, on the peripheral side of the second isolation opening, there is the second spacing between an edge of an orthographic projection, on the substrate, of a surface of the first sub-layer that faces the second sub-layer and the edge of the orthographic projection of the second sub-layer on the substrate.

In an embodiment according to the present application, the isolation structure further includes a third sub-layer located on a side of the first sub-layer that faces the substrate.

In an embodiment according to the present application, the orthographic projection of the first sub-layer on the substrate is within an orthographic projection of the third sub-layer on the substrate.

In an embodiment according to the present application, the display panel further includes a pixel define layer, the pixel define layer being located between the substrate and the isolation structure, and the pixel define layer including a pixel defining portion and a pixel opening enclosed by the pixel defining portion, the pixel opening being in communication with the isolation opening, where the light-emitting unit is located within the pixel opening; and the low-density layer includes a first segment and a second segment that are connected to each other, an orthographic projection of the first segment on the substrate being within an orthographic projection of the pixel opening on the substrate, and the second segment covering a sidewall of the isolation structure that faces the isolation opening, where a thickness of the first segment of the at least one first encapsulation portion is less than a thickness of the first segment of the second encapsulation portion in a thickness direction of the display panel; and/or a thickness of the second segment of the at least one first encapsulation portion is less than a thickness of the second segment of the second encapsulation portion in a thickness direction perpendicular to the display panel.

In an embodiment according to the present application, the second segment has a side edge that faces away from a side of the isolation structure, and an orthographic projection of the side edge of the at least one encapsulation portion on the substrate is on a side of the orthographic projection of the second sub-layer on the substrate that faces the isolation opening.

In an embodiment according to the present application, the low-density layer further includes a third segment connected to the second segment and located on a side of the isolation structure that faces away from the substrate.

In an embodiment according to the present application, the third segment of each encapsulation portion is spaced apart from each other.

In an embodiment according to the present application, a thickness of the third segment of the first encapsulation portion is less than a thickness of the third segment of the second encapsulation portion in the thickness direction of the display panel.

In an embodiment according to the present application, the first segment or the third segment or both of the first encapsulation portion have a thickness of 950 nanometers to 1150 nanometers.

In an embodiment according to the present application, the first segment or the third segment or both of the second encapsulation portion have a thickness of 1250 nanometers to 1450 nanometers.

In an embodiment according to the present application, the isolation opening further includes a third isolation opening, and the encapsulation portion includes a third encapsulation portion located within the third isolation opening, where a film thickness of the low-density layer of at least one second encapsulation portion is less than a film thickness of the low-density layer of the third encapsulation portion.

In an embodiment according to the present application, on a peripheral side of the third isolation opening, there is a third spacing between an edge of the orthographic projection of the first sub-layer on the substrate and an edge of the orthographic projection of the second sub-layer on the substrate, the second spacing being less than or equal to the third spacing.

In an embodiment according to the present application, on the peripheral side of the third isolation opening, there is the third spacing between an edge of an orthographic projection, on the substrate, of a surface of the first sub-layer that faces the second sub-layer and the edge of the orthographic projection of the second sub-layer on the substrate.

In an embodiment according to the present application, a thickness of the first segment of the at least one second encapsulation portion is less than a thickness of the first segment of the third encapsulation portion in the thickness direction of the display panel; and/or a thickness of the second segment of the at least one second encapsulation portion is less than a thickness of the second segment of the third encapsulation portion in a thickness direction perpendicular to the display panel.

In an embodiment according to the present application, a thickness of the third segment of the second encapsulation portion is less than a thickness of the third segment of the third encapsulation portion in the thickness direction of the display panel.

In an embodiment according to the present application, the first segment or the third segment or both of the third encapsulation portion have a thickness of 1500 nanometers to 1700 nanometers.

In an embodiment according to the present application, the light-emitting unit includes a first light-emitting unit located within the first isolation opening, a second light-emitting unit located within the second isolation opening, and a third light-emitting unit located within the third isolation opening, the first light-emitting unit, the second light-emitting unit, and the third light-emitting unit emitting light of different colors.

In an embodiment according to the present application, the display panel further includes a first electrode located on a side of the light-emitting unit that faces the substrate and a second electrode located on a side of the light-emitting unit that faces away from the substrate, the second electrode being located on a side of the encapsulation portion that faces the substrate.

In an embodiment according to the present application, the first high-density layer is disposed on a side of the low-density layer that faces away from the substrate; or the low-density layer is disposed on a side of the first high-density layer that faces away from the substrate.

In an embodiment according to the present application, the low-density layer is disposed on a side of the first high-density layer that faces away from the substrate, and the encapsulation portion further includes a second high-density layer disposed on a side of the low-density layer that faces away from the substrate.

In an embodiment according to the present application, a silicon nitride content in a material of the low-density layer is less than a silicon nitride content in a material of the first high-density layer.

In an embodiment according to the present application, a silicon nitride content in a material of the low-density layer is less than a silicon nitride content in a material of the second high-density layer.

In an embodiment according to the present application, the display panel further includes a second encapsulation layer located on a side of the first encapsulation layer that faces away from the substrate.

In an embodiment according to the present application, a material of the second encapsulation layer includes an organic material.

In an embodiment according to the present application, the display panel further includes a third encapsulation layer located on a side of the second encapsulation layer that faces away from the substrate.

In an embodiment according to the present application, a material of the third encapsulation layer includes an inorganic material.

An embodiment of the present application further provides a display panel. The display panel includes: a substrate; an isolation structure disposed on a side of the substrate, where the isolation structure encloses an isolation opening, and the isolation structure includes a first sub-layer and a second sub-layer, the second sub-layer being located on a side of the first sub-layer that faces away from the substrate, and the second sub-layer protruding toward the isolation opening by a spacing relative to the first sub-layer; a light-emitting layer including a light-emitting unit at least partially located within the isolation opening; and a first encapsulation layer including an encapsulation portion configured to encapsulate each light-emitting unit, where the encapsulation portion includes a first high-density layer and a low-density layer that are stacked, a film thickness of the low-density layer of each encapsulation portion being linearly correlated with the corresponding spacing.

In an embodiment according to the present application, the isolation opening includes a first isolation opening and a second isolation opening, where on a peripheral side of the first isolation opening, the spacing includes a first spacing by which the second sub-layer protrudes toward the isolation opening relative to the first sub-layer; and on a peripheral side of the second isolation opening, the spacing includes a second spacing by which the second sub-layer protrudes toward the isolation opening relative to the first sub-layer, the first spacing being less than the second spacing; and the encapsulation portion includes a first encapsulation portion located within the first isolation opening and a second encapsulation portion located within the second isolation opening, where a film thickness of the low-density layer of at least one first encapsulation portion is less than a film thickness of the low-density layer of the second encapsulation portion.

An embodiment of the present application further provides a display apparatus, including a display panel according to any one of the embodiments.

An embodiment of the present application further provides a method for manufacturing a display panel. The method includes:
forming an isolation structure on a side of a substrate, where the isolation structure encloses an isolation opening, the isolation opening including a first isolation opening and a second isolation opening;
preparing a first light-emitting unit in a region where the first isolation opening is located, and preparing a first encapsulation portion on a side of the first light-emitting unit that faces away from the substrate; and
preparing a second light-emitting unit in a region where the second isolation opening is located, and preparing a second encapsulation portion on a side of the second light-emitting unit that faces away from the substrate, where the first encapsulation portion and the second encapsulation portion each include a first high-density layer and a low-density layer that are stacked, a film thickness of the low-density layer of the first encapsulation portion being less than a film thickness of the low-density layer of the second encapsulation portion.

In an embodiment according to the present application, the step of preparing a first light-emitting unit in a region where the first isolation opening is located, and preparing a first encapsulation portion on a side of the first light-emitting unit that faces away from the substrate includes:
sequentially forming a first light-emitting material layer and a first encapsulation material layer in the isolation opening and on the side of the isolation structure that faces away from the substrate; and
removing the first encapsulation material layer and the first light-emitting material layer in the region where the second isolation opening is located, to form the first encapsulation portion and the first light-emitting unit.

In an embodiment according to the present application, the first light-emitting material layer in the region where the second isolation opening is located is removed by using wet etching.

In an embodiment according to the present application, the isolation opening further includes a third isolation opening. After the step of preparing the second encapsulation portion on the side of the second light-emitting unit that faces away from the substrate, the method further includes:
preparing a third light-emitting unit in the third isolation opening, and preparing a third encapsulation portion on a side of the third light-emitting unit that faces away from the substrate, a film thickness of the low-density layer of the first encapsulation portion being less than a film thickness of the low-density layer of the third encapsulation portion.

In an embodiment according to the present application, the film thickness of the low-density layer of the second encapsulation portion is less than the film thickness of the low-density layer of the third encapsulation portion.

In an embodiment according to the present application, a film thickness of the low-density layer of at least one first encapsulation portion is less than the film thickness of the low-density layer of the second encapsulation portion. A larger film thickness of the low-density layer of the second encapsulation portion facilitates filling a sidewall of the isolation structure that faces the second isolation opening, to reduce the occurrence of recession of the second encapsulation portion and then improve the reliability of the encapsulation portion, thereby improving the usage performance of the display panel.

### BRIEF DESCRIPTION OF THE DRAWINGS

By reading the following detailed description of non-limiting embodiments made with reference to the drawings, the other embodiments of the present application will become more apparent, in which the same or similar features are denoted by the same or similar reference signs.

FIG. 1 is a schematic structural diagram of a display panel according to an embodiment of the present application;

FIG. 2 is a cross-sectional view taken along line CC in FIG. 1;

FIG. 3 is a schematic partial structural diagram of another display panel according to an embodiment of the present application;

FIG. 4 is a schematic partial structural diagram of still another display panel according to an embodiment of the present application;

FIG. 5 is a flowchart of a method for manufacturing a display panel according to an embodiment of the present application; and

FIGS. 6 to 9 are schematic diagrams of a process of a method for manufacturing a display panel according to an embodiment of the present application.

List of reference signs: 100. substrate; 200. isolation structure; 201. first sub-layer; 202. second sub-layer; 203. third sub-layer; 204. sidewall; 210. isolation opening; 211. first isolation opening; 212. second isolation opening; 213. third isolation opening; 300. light-emitting unit; 310. first light-emitting unit; 311. First light-emitting material layer; 320. second light-emitting unit; 330. third light-emitting unit; 340. first electrode; 350. second electrode; 400. encapsulation portion; 400a. first high-density layer; 400b. low-density layer; 400c. second high-density layer; 401. first segment; 402. second segment; 403. third segment; 404. side edge; 410. first encapsulation portion; 411. first encapsulation material layer; 420. second encapsulation portion; 430. third encapsulation portion; 500. pixel defining portion; 510. pixel opening; 600. second encapsulation layer; 700. third encapsulation layer; a. first spacing; b. second spacing; c. third spacing; and Z. thickness direction.

### DETAILED DESCRIPTION OF THE EMBODIMENTS

The features and exemplary embodiments of the present application in various embodiments are described in detail below. In the following detailed description, many specific details are set forth to comprehensively understand the present application. However, it will be very apparent to those skilled in the art that the present application may be implemented without some of these specific details. The following description of the embodiments are merely to provide a better understanding for the present application by illustrating examples of the present application. In the drawings and the following description, at least part of known structures and techniques are not shown to avoid unnecessary ambiguousness of the present application; and for the ease of clarity, the dimensions of part of the structure may be enlarged. In addition, the features, structures, or characteristics described below may be combined, in any suitable manner, in one or more embodiments.

In the description of the present application, it should be noted that “a plurality of” means two or more, unless otherwise specified. The orientation or position relationship indicated by the terms “upper”, “lower”, “left”, “right”, “inner”, “outer”, etc. is merely for the convenience of describing the present application and simplifying the description, rather than indicating or implying that an apparatus or element referred to must have a particular orientation or be constructed and operated in a particular orientation, and therefore should not be construed as limiting the present application. Moreover, the terms such as “first” and “second” are merely used for the illustrative purpose, and should not be construed as indicating or implying the relative importance.

The orientation terms used in the following description all indicate directions shown in the accompanying drawings, and do not limit the specific structure of the embodiment of the present application. In the description of the present application, it should also be noted that unless otherwise explicitly specified and defined, the terms “mounting” and “connection” should be understood in a broad sense, for example, they may be a fixed connection, a detachable connection, or an integrated connection, and may be a direct connection, or an indirect connection. For those of ordinary skill in the art, the specific meanings of the terms mentioned above in the present application may be construed according to specific circumstances.

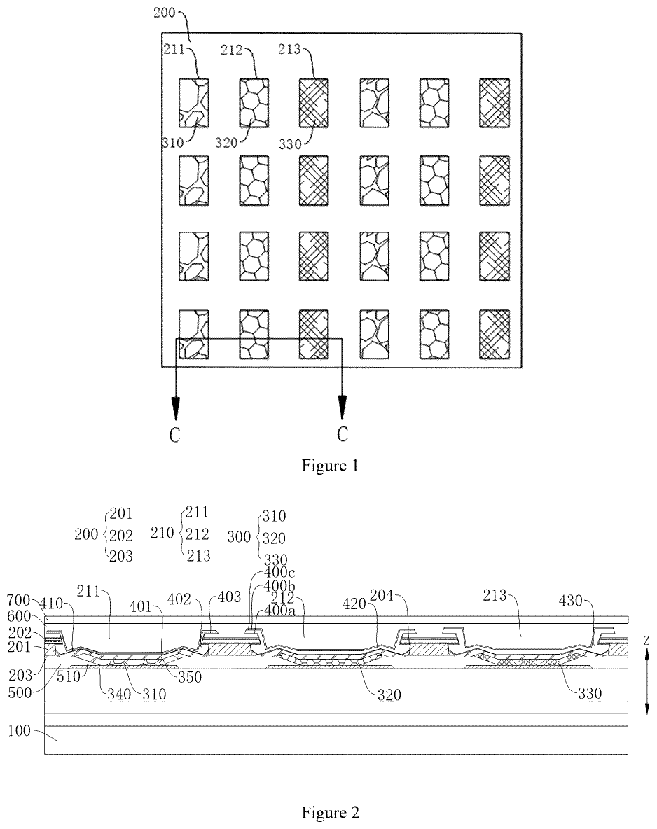

As shown in FIGS. 1 and 2, an embodiment of the present application provides a display panel. The display panel includes: a substrate 100, an isolation structure 200, a light-emitting layer, and a first encapsulation layer. The isolation structure 200 is disposed on a side of the substrate 100, and the isolation structure 200 encloses an isolation opening 210. The isolation opening 210 includes a first isolation opening 211 and a second isolation opening 212. The light-emitting layer includes a light-emitting unit 300 at least partially located within the isolation opening 210. The first encapsulation layer includes an encapsulation portion 400 configured to encapsulate each light-emitting unit 300. The encapsulation portion 400 includes a first high-density layer 400a and a low-density layer 400b that are stacked, and the encapsulation portion 400 includes a first encapsulation portion 410 located within the first isolation opening 211 and a second encapsulation portion 420 located within the second isolation opening 212. A film thickness of the low-density layer 400b of at least one first encapsulation portion 410 is less than a film thickness of the low-density layer 400b of the second encapsulation portion 420. In one embodiment, a difference between the low-density layer and the high-density layer lies in a varying content of silicon nitride per unit volume.

In this embodiment, the isolation structure 200 is disposed on the substrate 100 and encloses a plurality of isolation openings 210 to separate the light-emitting layer into light-emitting units 300 that are isolated from each other, and the light-emitting units 300 are located within the isolation openings 210, and the isolation structure 200 can reduce optical crosstalk between different light-emitting units 300, thereby improving the display effect. Moreover, the light-emitting units 300 may be prepared without the use of a precision mask, which can reduce the development and use of the precision mask and lower preparation costs. The first encapsulation layer includes the encapsulation portion 400 configured to encapsulate each light-emitting unit 300, and the encapsulation portion 400 includes the first high-density layer 400a and the low-density layer 400b that are stacked. The first high-density layer 400a can reduce the ingress of water, oxygen, etc. into the light-emitting unit 300 to cause damage to the light-emitting unit 300, thereby improving the reliability of the light-emitting unit 300. The low-density layer 400b exhibits better ductility, thereby improving the encapsulation effect of the encapsulation portion 400. In some embodiments, the light-emitting unit 300 located within the first isolation opening 211 and the light-emitting unit 300 located within the second isolation opening 212 are formed sequentially. During formation of the light-emitting unit 300 within the first isolation opening 211, a light-emitting material in the second isolation opening 212 needs to be etched away, resulting in a greater degree of erosion on a sidewall 204 of the isolation structure 200 that faces the second isolation opening 212. During formation of the second encapsulation portion 420 within the second isolation opening 212, the second encapsulation portion 420 is recessed toward the sidewall 204. The recessed position is prone to damage in subsequent preparation processes, leading to an encapsulation failure. However, in this embodiment, the encapsulation portion 400 includes the first encapsulation portion 410 located within the first isolation opening 211 and the second encapsulation portion 420 located within the second isolation opening 212, and the film thickness of the low-density layer 400b of the at least one first encapsulation portion 410 is less than the film thickness of the low-density layer 400b of the second encapsulation portion 420. A larger film thickness of the low-density layer 400b of the second encapsulation portion 420 facilitates filling the sidewall 204 of the isolation structure 200 that faces the second isolation opening 212, to reduce the occurrence of recession of the second encapsulation portion 420 and then improve the reliability of the encapsulation portion 400, thereby improving the usage performance of the display panel.

As shown in FIG. 2, in some embodiments, the isolation structure 200 includes a first sub-layer 201 and a second sub-layer 202. The second sub-layer 202 is located on a side of the first sub-layer 201 that faces away from the substrate 100, and an orthographic projection of the first sub-layer 201 on the substrate 100 is within an orthographic projection of the second sub-layer 202 on the substrate 100.

In these embodiments, the first sub-layer 201 and the second sub-layer 202 are disposed to form the isolation structure 200, the orthographic projection, on the substrate 100, of the first sub-layer 201 disposed close to the substrate 100 is within the orthographic projection of the second sub-layer 202 on the substrate 100, the area of the second sub-layer 202 is greater than the area of the first sub-layer 201, and the second sub-layer 202 covers the surface of the first sub-layer 201 that is close to the second sub-layer 202, in which case the first sub-layer 201 is recessed relative to the second sub-layer 202 in a direction facing away from the isolation opening 210. During preparation of the light-emitting layer, the light-emitting layer has a large drop at an edge of the isolation structure 200, and the first sub-layer 201 is recessed relative to the second sub-layer 202, which makes it difficult for the light-emitting layer to be continuous at the edge of the isolation structure 200, resulting in breakage. The light-emitting layer breaks to form light-emitting units 300 which are isolated from each other.

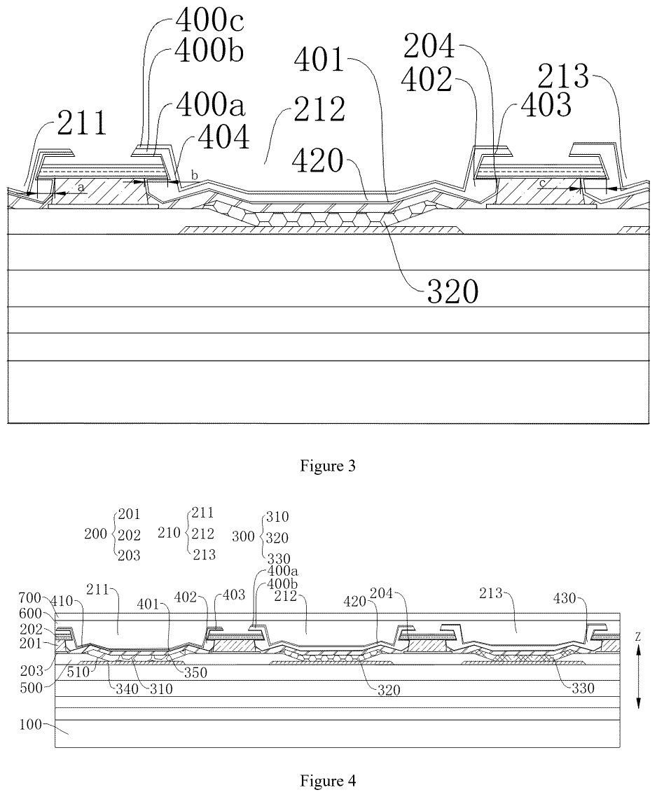

As shown in FIGS. 2 and 3, in some embodiments, on a peripheral side of the first isolation opening 211, there is a first spacing a between an edge of the orthographic projection of the first sub-layer 201 on the substrate 100 and an edge of the orthographic projection of the second sub-layer 202 on the substrate 100; and on a peripheral side of the second isolation opening 212, there is a second spacing b between an edge of the orthographic projection of the first sub-layer 201 on the substrate 100 and an edge of the orthographic projection of the second sub-layer 202 on the substrate 100, the first spacing a being less than or equal to the second spacing b.

In these embodiments, the first spacing a being less than or equal to the second spacing b means the degree of recession of the first sub-layer 201 relative to the second sub-layer 202 on the peripheral side of the first isolation opening 211 being less than or equal to the degree of recession of the first sub-layer 201 relative to the second sub-layer 202 on the peripheral side of the second isolation opening 212. The film thickness of the low-density layer 400b of the second encapsulation portion 420 is set to be greater than the film thickness of the low-density layer 400b of the first encapsulation portion 410, which allows the second encapsulation portion 420 to cover, to a greater extent, a recessed portion of the isolation structure 200 in the second isolation opening 212, to reduce the degree of recession formed in the second encapsulation portion 420, thereby improving the reliability of the second encapsulation portion 420.

In one embodiment, as shown in FIG. 3, on the peripheral side of the first isolation opening 211, there is the first spacing a between an edge of the orthographic projection, on the substrate 100, of a surface of the first sub-layer 201 that faces the second sub-layer 202 and the edge of the orthographic projection of the second sub-layer 202 on the substrate 100. The area of the surface of the first sub-layer 201 that faces the second sub-layer 202 is less than the area of the second sub-layer 202, forming a recession, and the first spacing a is the degree of recession of the sidewall 204 on a side of the isolation structure 200 that faces the first isolation opening 211.

In one embodiment, as shown in FIG. 3, on the peripheral side of the second isolation opening 212, there is the second spacing b between an edge of the orthographic projection, on the substrate 100, of a surface of the first sub-layer 201 that faces the second sub-layer 202 and the edge of the orthographic projection of the second sub-layer 202 on the substrate 100. The area of the surface of the first sub-layer 201 that faces the second sub-layer 202 is less than the area of the second sub-layer 202, forming a recession, and the second spacing b is the degree of recession of the sidewall 204 on a side of the isolation structure 200 that faces the second isolation opening 212.

In one embodiment, as shown in FIG. 2, the isolation structure 200 further includes a third sub-layer 203. The third sub-layer 203 is located on a side of the first sub-layer 201 that faces the substrate 100. During lateral etching of the first sub-layer 201, the third sub-layer 203 may protect the film layer on the side of the substrate 100.

In one embodiment, as shown in FIG. 2, the orthographic projection of the first sub-layer 201 on the substrate 100 is within an orthographic projection of the third sub-layer 203 on the substrate 100, thereby improving the protective effect of the third sub-layer 203 on the film layer on the side of the substrate 100.

In one embodiment, a material of the first sub-layer 201 may include aluminum, silver or copper.

In one embodiment, a material of the second sub-layer 202 may include titanium or molybdenum. During etching, the degree of etching of the first sub-layer 201 will be greater than the degree of etching of the second sub-layer 202, and etching away the light-emitting material in the second isolation opening 212 result in a greater degree of erosion on the sidewall 204 of the first sub-layer 201 that faces the second isolation opening 212 than that in the second sub-layer 202, thereby making the degree of recession of the sidewall 204 of the isolation structure 200 that faces the second isolation opening 212 greater than the degree of recession of the sidewall 204 of the isolation structure 200 that faces the first isolation opening 211.

In one embodiment, a material of the third sub-layer 203 may include titanium or molybdenum.

For specific designs of the isolation structure 200, reference may be made to existing Patent Application Nos, such as 202310771124.9, 202310740412.8, 202310771071.0, 202311017132.0, PCT/CN 2023/134518, and 202311091555.7 in which related content of the isolation structure 200 is described.

As shown in FIG. 2, in some embodiments, the display panel further includes a pixel define layer, the pixel define layer being located between the substrate 100 and the isolation structure 200, and the pixel define layer including a pixel defining portion 500 and a pixel opening 510 enclosed by the pixel defining portion 500, the pixel opening 510 being in communication with the isolation opening 210, where the light-emitting unit 300 is located within the pixel opening 510. The low-density layer 400b includes a first segment 401 and a second segment 402 that are connected to each other, an orthographic projection of the first segment 401 on the substrate 100 being within an orthographic projection of the pixel opening 510 on the substrate 100, and the second segment 402 covering the sidewall 204 of the isolation structure 200 that faces the isolation opening 210.

In these embodiments, the first segment 401 covers a side of the light-emitting unit 300 that faces away from the substrate 100, and the second segment 402 covers the sidewall 204 of the isolation structure 200 that faces the isolation opening 210, to increase the distribution area of the encapsulation portion 400, thereby improving the encapsulation effect.

In one embodiment, as shown in FIG. 2, the thickness of the first segment 401 of the at least one first encapsulation portion 410 is less than the thickness of the first segment 401 of the second encapsulation portion 420 in a thickness direction Z of the display panel. During formation of the second encapsulation portion 420, in order to increase the thickness of the second segment 402 of the second encapsulation portion 420 to evaporate a large portion of the material of the encapsulation portion 400, the film thickness of the first segment 401 of the second encapsulation portion 420 is made greater than the film thickness of the first segment 401 of the first encapsulation portion 410.

In one embodiment, as shown in FIG. 2, the thickness of the second segment 402 of the at least one first encapsulation portion 410 is less than the thickness of the second segment 402 of the second encapsulation portion 420 in the thickness direction Z perpendicular to the display panel. During formation of the second encapsulation portion 420, in order to increase the thickness of the second segment 402 of the second encapsulation portion 420 to evaporate a large portion of the material of the low-density layer 400b, the film thickness of the second segment 402 of the second encapsulation portion 420 is made greater than the film thickness of the second segment 402 of the first encapsulation portion 410, to reduce the degree of recession of the second segment 402 of the second encapsulation portion 420.

In one embodiment, the thickness of the second segment 402 of the first encapsulation portion 410 being less than the thickness of the second segment 402 of the second encapsulation portion 420 may mean the thickness of part of the second segment 402 of the first encapsulation portion 410 that covers the second sub-layer 202 being less than the thickness of part of the second segment 402 of the second encapsulation portion 420 that covers the second sub-layer 202 in the thickness direction Z perpendicular to the display panel.

As shown in FIG. 2, in some embodiments, the second segment 402 has a side edge 404 that faces away from a side of the isolation structure 200, an orthographic projection of the side edge 404 of the at least one encapsulation portion 400 on the substrate 100 being on a side of the orthographic projection of the second sub-layer 202 on the substrate 100 that faces the isolation opening 210.

In these embodiments, the orthographic projection of the side edge 404 of the at least one encapsulation portion 400 on the substrate 100 being on the side of the orthographic projection of the second sub-layer 202 on the substrate 100 that faces the isolation opening 210 enables the second side edge 404 to protrude from the second sub-layer 202 in a direction facing away from the isolation structure 200, thereby improving the reliability of the encapsulation portion 400.

As shown in FIG. 2, in some embodiments, the low-density layer 400b further includes a third segment 403. The third segment 403 is connected to the second segment 402 and located on a side of the isolation structure 200 that faces away from the substrate 100.

In these embodiments, the third segment 403 covers part of the side of the isolation structure 200 that faces away from the substrate 100, to increase the distribution area of the encapsulation portion 400.

In one embodiment, as shown in FIG. 2, the third segment 403 of each encapsulation portion 400 is spaced apart from each other, enabling independent encapsulation of each encapsulation portion 400, thereby mitigating the problem that the yield of the light-emitting unit 300 is affected by water or oxygen intrusion.

In one embodiment, as shown in FIG. 2, the thickness of the third segment 403 of the first encapsulation portion 410 is less than the thickness of the third segment 403 of the second encapsulation portion 420 in the thickness direction Z of the display panel. In order to increase the thickness of the second segment 402 of the second encapsulation portion 420 to evaporate a large portion of a material of the low-density layer 400b, the film thickness of the third segment 403 of the second encapsulation portion 420 is made greater than the film thickness of the third segment 403 of the first encapsulation portion 410.

In one embodiment, the first segment 401 or the third segment 403 or both of the first encapsulation portion 410 have a thickness of 950 nanometers to 1150 nanometers. The first segment 401 and the third segment 403 of the first encapsulation portion 410 may each have a thickness of 950 nanometers, 1000 nanometers, 1050 nanometers, 1100 nanometers, 1150 nanometers, etc.

In one embodiment, the first segment 401 or the third segment 403 or both of the second encapsulation portion 420 have a thickness of 1250 nanometers to 1450 nanometers. The first segment 401 and the third segment 403 of the second encapsulation portion 420 may each have a thickness of 1250 nanometers, 1300 nanometers, 1350 nanometers, 1400 nanometers, 1450 nanometers, etc.

As shown in FIG. 2, in some embodiments, the isolation opening 210 further includes a third isolation opening 213, and the encapsulation portion 400 includes a third encapsulation portion 430 located within the third isolation opening 213, where the film thickness of the low-density layer 400b of the at least one second encapsulation portion 420 is less than a film thickness of the low-density layer 400b of the third encapsulation portion 430.

In some embodiments, the light-emitting unit 300 located within the first isolation opening 211, the light-emitting unit 300 located within the second isolation opening 212, and the light-emitting unit 300 located within the third isolation opening 213 are formed sequentially. During formation of the light-emitting unit 300 within the first isolation opening 211, light-emitting materials in the second isolation opening 212 and the third isolation opening 213 need to be etched away, resulting in a greater degree of erosion on a sidewall 204 of the isolation structure 200 that faces the third isolation opening 213. During formation of the light-emitting unit 300 within the second isolation opening 212, a light-emitting material in the third isolation opening 213 needs to be etched away, enabling the sidewall 204 of the isolation structure 200 that faces the third isolation opening 213 to be further eroded. During formation of the third encapsulation portion 430 within the third isolation opening 213, the third encapsulation portion 430 is recessed toward the sidewall 204. The recessed position is prone to damage in subsequent preparation processes, leading to an encapsulation failure. In these embodiments, a larger film thickness of the low-density layer 400b of the third encapsulation portion 430 facilitates filling the sidewall 204 of the isolation structure 200 that faces the third isolation opening 213, to reduce the occurrence of recession of the third encapsulation portion 430 and then improve the reliability of the encapsulation portion 400, thereby improving the usage performance of the display panel.

As shown in FIGS. 2 and 3, in some embodiments, on a peripheral side of the third isolation opening 213, there is a third spacing c between an edge of the orthographic projection of the first sub-layer 201 on the substrate 100 and an edge of the orthographic projection of the second sub-layer 202 on the substrate 100, the second spacing b being less than or equal to the third spacing c.

In these embodiments, the second spacing b being less than or equal to the third spacing c means the degree of recession of the first sub-layer 201 relative to the second sub-layer 202 on the peripheral side of the second isolation opening 212 being less than or equal to the degree of recession of the first sub-layer 201 relative to the second sub-layer 202 on the peripheral side of the third isolation opening 213. The film thickness of the low-density layer 400b of the third encapsulation portion 430 is set to be greater than the film thickness of the low-density layer 400b of the second encapsulation portion 420, which allows the third encapsulation portion 430 to cover, to a greater extent, a recessed portion of the isolation structure 200 in the third isolation opening 213, to reduce the degree of recession formed in the third encapsulation portion 430, thereby improving the reliability of the third encapsulation portion 430.

In one embodiment, as shown in FIG. 3, on the peripheral side of the third isolation opening 213, there is the third spacing c between an edge of the orthographic projection, on the substrate 100, of a surface of the first sub-layer 201 that faces the second sub-layer 202 and the edge of the orthographic projection of the second sub-layer 202 on the substrate 100. The area of the surface of the first sub-layer 201 that faces the second sub-layer 202 is less than the area of the second sub-layer 202, forming a recession, and the third spacing c is the degree of recession of the sidewall 204 on a side of the isolation structure 200 that faces the third isolation opening 213.

In one embodiment, as shown in FIG. 2, the thickness of the first segment 401 of the at least one second encapsulation portion 420 is less than the thickness of the first segment 401 of the third encapsulation portion 430 in the thickness direction Z of the display panel. During formation of the third encapsulation portion 430, in order to increase the thickness of the second segment 402 of the third encapsulation portion 430 to evaporate a large portion of a material of the low-density layer 400b, the film thickness of the first segment 401 of the third encapsulation portion 430 is made greater than the film thickness of the first segment 401 of the second encapsulation portion 420.

In one embodiment, as shown in FIG. 2, the thickness of the second segment 402 of the at least one second encapsulation portion 420 is less than the thickness of the second segment 402 of the third encapsulation portion 430 in the thickness direction Z perpendicular to the display panel, thereby reducing the degree of recession of the second segment 402 of the third encapsulation portion 430.

In one embodiment, the thickness of the second segment 402 of the second encapsulation portion 420 being less than the thickness of the second segment 402 of the third encapsulation portion 430 may mean the thickness of part of the second segment 402 of the second encapsulation portion 420 that covers the second sub-layer 202 being less than the thickness of part of the second segment 402 of the third encapsulation portion 430 that covers the second sub-layer 202 in the thickness direction Z perpendicular to the display panel.

In one embodiment, as shown in FIG. 2, the thickness of the third segment 403 of the second encapsulation portion 420 is less than the thickness of the third segment 403 of the third encapsulation portion 430 in the thickness direction Z of the display panel. In order to increase the thickness of the second segment 402 of the third encapsulation portion 430 to evaporate a large portion of a material of the low-density layer 400b, the film thickness of the third segment 403 of the third encapsulation portion 430 is made greater than the film thickness of the third segment 403 of the second encapsulation portion 420.

In one embodiment, the first segment 401 or the third segment 403 or both of the third encapsulation portion 430 have a thickness of 1500 nanometers to 1700 nanometers. The first segment 401 and the third segment 403 of the third encapsulation portion 430 may each have a thickness of 1500 nanometers, 1550 nanometers, 1600 nanometers, 1650 nanometers, 1700 nanometers, etc.

In one embodiment, as shown in FIG. 2, the light-emitting unit 300 include a first light-emitting unit 310 located within the first isolation opening 211, a second light-emitting unit 320 located within the second isolation opening 212, and a third light-emitting unit 330 located within the third isolation opening 213, the first light-emitting unit 310, the second light-emitting unit 320, and the third light-emitting unit 330 emitting light of different colors.

In one embodiment, as shown in FIG. 2, the display panel further includes a first electrode 340 located on a side of the light-emitting unit 300 that faces the substrate 100 and a second electrode 350 located on a side of the light-emitting units 300 that faces away from the substrate 100, the second electrode 350 being located on a side of the encapsulation portion 400 that faces the substrate 100. The first electrode 340 is exposed from the pixel opening 510. One of the first electrode 340 and the second electrode 350 serves as an anode of the light-emitting unit 300, and the other serves as a cathode of the light-emitting unit 300.

As shown in FIG. 4, in some embodiments, the first high-density layer 400a is disposed on a side of the low-density layer 400b that faces away from the substrate 100.

In these embodiments, the first high-density layer 400a is located on the side of the low-density layer 400b that faces away from the substrate 100. The first high-density layer 400a covers the first segment 401, the second segment 402, and the third segment 403. The first high-density layer 400a covers the side of the light-emitting unit 300 that faces away from the substrate 100, the side of the isolation structure 200 that faces the isolation opening 210, and the side of the isolation opening 210 that faces away from the substrate 100, thereby improving the encapsulation effect of the encapsulation portion 400.

As shown in FIG. 2, in some other embodiments, the low-density layer 400b is disposed on a side of the first high-density layer 400a that faces away from the substrate 100.

In these embodiments, the first segment 401, the second segment 402, and the third segment 403 are all covered by the first high-density layer 400a. The first high-density layer 400a covers the side of the light-emitting unit 300 that faces away from the substrate 100, the side of the isolation structure 200 that faces the isolation opening 210, and the side of the isolation opening 210 that faces away from the substrate 100, thereby improving the encapsulation effect of the encapsulation portion 400.

In one embodiment, as shown in FIGS. 2 and 3, the encapsulation portion 400 further includes a second high-density layer 400c. The second high-density layer 400c is disposed on a side of the low-density layer 400b that faces away from the substrate 100, the low-density layer 400b being located between the first high-density layer 400a and the second high-density layer 400c. The second high-density layer 400c is provided to further improve the encapsulation effect of the encapsulation portion 400.

In one embodiment, a silicon nitride content in a material of the low-density layer 400b is less than a silicon nitride content in a material of the first high-density layer 400a. In the preparation process of the encapsulation portion 400, adding more hydrogen during the formation of the low-density layer 400b can suppress the bonding strength between nitrogen and silicon, thereby reducing the silicon nitride content in the low-density layer 400b, whereas adding less or no hydrogen during the formation of the first high-density layer 400a can enhance the bonding strength between nitrogen and silicon, thereby forming the first high-density layer 400a with higher density.

In one embodiment, the a silicon nitride content in a material of the low-density layer 400b is less than the a silicon nitride content in a material of the second high-density layer 400c. In the preparation process of the encapsulation portion 400, adding more hydrogen in the formation of the low-density layer 400b can suppress the bonding strength between nitrogen and silicon, thereby reducing the density of the low-density layer 400b, whereas adding less or no hydrogen in the formation of the second high-density layer 400c can enhance the bonding strength between nitrogen and silicon, thereby forming the second high-density layer 400c with higher density.

In one embodiment, the density of the low-density layer 400b is less than the density of the first high-density layer 400a, and/or the density of the low-density layer 400b is less than the density of the second high-density layer 400c.

As shown in FIG. 2, in some embodiments, the display panel further includes a second encapsulation layer 600. The second encapsulation layer 600 is located on a side of the first encapsulation layer that faces away from the substrate 100.

In these embodiments, the second encapsulation layer 600 fills each isolation opening 210 and the side of the isolation structure 200 that faces away from the substrate 100. In one embodiment, a material of the second encapsulation layer 600 includes an organic material, and the second encapsulation layer 600 may have better fluidity, and the surface on a side of the second encapsulation layer 600 that faces away from the substrate 100 is flat.

In one embodiment, as shown in FIG. 2, the display panel further includes a third encapsulation layer 700. The third encapsulation layer 700 is located on the side of the second encapsulation layer 600 that faces away from the substrate 100. In one embodiment, a material of the third encapsulation layer 700 includes an inorganic material, which can enhance the blocking effect of the display panel on water and oxygen to further improve the encapsulation effect of the display panel. As shown in FIGS. 1 and 2, an embodiment of the present application further provides a display panel. The display panel includes: a substrate 100, an isolation structure 200, a light-emitting layer, and a first encapsulation layer. The isolation structure 200 is disposed on a side of the substrate 100. The isolation structure 200 encloses an isolation opening 210. The isolation structure 200 includes a first sub-layer 201 and a second sub-layer 202, the second sub-layer 202 being located on a side of the first sub-layer 201 that faces away from the substrate 100, and the second sub-layer 202 protruding toward the isolation opening 210 by a spacing relative to the first sub-layer 201. The light-emitting layer includes a light-emitting unit 300 at least partially located within the isolation opening 210. The first encapsulation layer includes an encapsulation portion 400 configured to encapsulate each light-emitting unit 300, where the encapsulation portion 400 includes a first high-density layer 400a and a low-density layer 400b that are stacked, a film thickness of the low-density layer 400b of each encapsulation portion 400 being linearly correlated with the spacing.

In this embodiment, the second sub-layer 202 protrudes toward the isolation opening 210 by the spacing relative to the first sub-layer 201. A larger spacing indicates a greater degree of recession on the side of the isolation structure 200 that faces the isolation opening 210. The film thickness of the low-density layer 400b of each encapsulation portion 400 is linearly correlated with the spacing. The low-density layer 400b of the encapsulation portion 400 in a region where the isolation opening 210 enclosed by the isolation structure 200 with a larger spacing is located has a larger film thickness, thereby reducing the degree of recession of the encapsulation portion 400. The low-density layer 400b of the encapsulation portion 400 in a region where the isolation opening 210 enclosed by the isolation structure 200 with a smaller spacing is located has a smaller film thickness, thereby reducing the impact of the encapsulation portion 400 on the light emission of the light-emitting unit 300.

As shown in FIGS. 2 and 3, in some embodiments, the isolation opening 210 includes a first isolation opening 211 and a second isolation opening 212. On a peripheral side of the first isolation opening 211, the spacing includes a first spacing by which the second sub-layer 202 protrudes toward the isolation opening 210 relative to the first sub-layer 201; and on a peripheral side of the second isolation opening 212, the spacing includes a second spacing by which the second sub-layer 202 protrudes toward the isolation opening 210 relative to the first sub-layer 201, the first spacing being less than the second spacing. The encapsulation portion 400 includes a first encapsulation portion 410 located within the first isolation opening 211 and a second encapsulation portion 420 located within the second isolation opening 212, where a film thickness of the low-density layer 400b of at least one first encapsulation portion 410 is less than a film thickness of the low-density layer 400b of the second encapsulation portion 420.

In these embodiments, the first spacing being less than the second spacing means the degree of recession of the first sub-layer 201 relative to the second sub-layer 202 on the peripheral side of the first isolation opening 211 being less than or equal to the degree of recession of the first sub-layer 201 relative to the second sub-layer 202 on the peripheral side of the second isolation opening 212. The film thickness of the low-density layer 400b of the second encapsulation portion 420 is set to be greater than the film thickness of the low-density layer 400b of the first encapsulation portion 410, which allows the second encapsulation portion 420 to cover, to a greater extent, a recessed portion of the isolation structure 200 in the second isolation opening 212, to reduce the degree of recession formed in the second encapsulation portion 420, thereby improving the reliability of the second encapsulation portion 420.

In some embodiments, the features such as the encapsulation portion 400 and the isolation structure 200 are arranged as described above, which will not be repeated herein.

An embodiment of the present application further provides a display apparatus, including a display panel according to any one of the above-described embodiments. Since the display apparatus according to the embodiment of the present application includes the display panel according to any one of the above-described embodiments, the display apparatus according to the embodiment of the present application has the beneficial effects of the display panel according to any one of the above-described embodiments, which will not be repeated herein.

The display apparatus in the embodiment of the present application includes, but is not limited to, devices having a display function, such as a cell phone, a personal digital assistant (PDA), a tablet computer, an e-book reader, a television, an access control system, a smart fixed-line telephone, or a console.

An embodiment of the present application further provides a method for manufacturing a display panel. As shown in FIG. 5, the method includes the following steps.

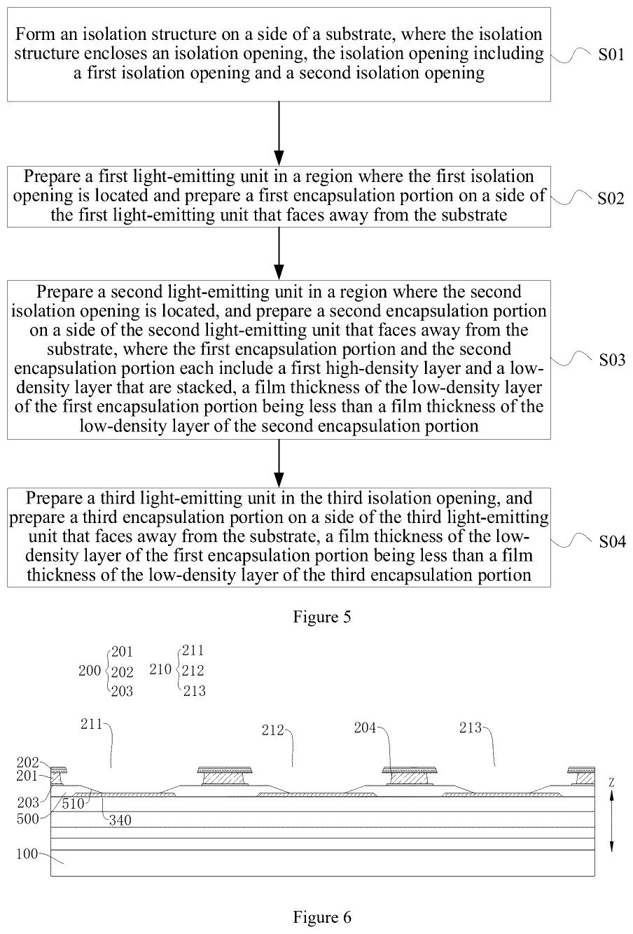

Step S01: As shown in FIG. 6, an isolation structure 200 is prepared on a side of a substrate 100, where the isolation structure 200 encloses an isolation opening 210, the isolation opening 210 including a first isolation opening 211 and a second isolation opening 212.

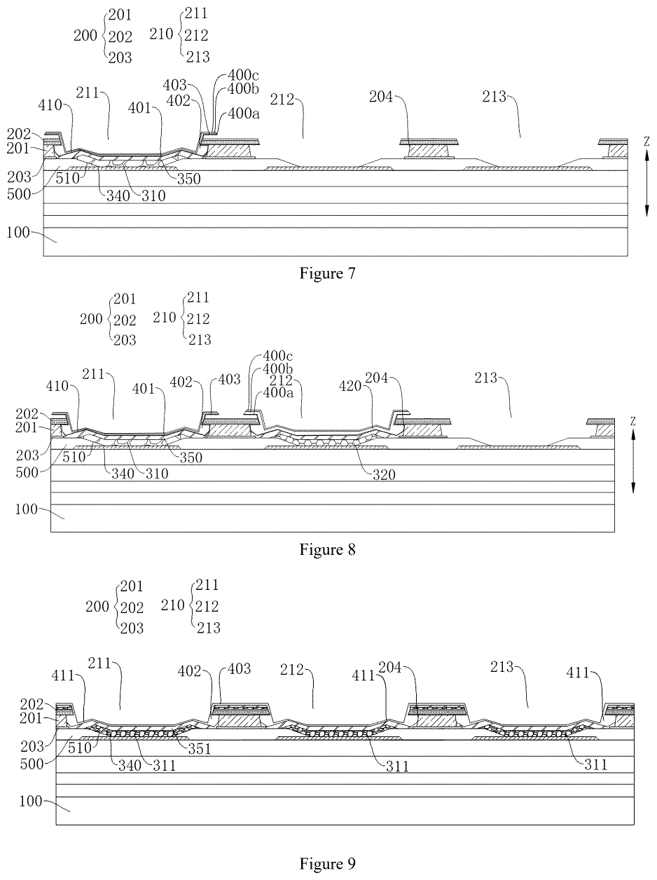

Step S02: As shown in FIG. 7, a first light-emitting unit 310 is prepared in a region where the first isolation opening 211 is located, and a first encapsulation portion 410 is prepared on a side of the first light-emitting unit 310 that faces away from the substrate 100.

Step S03: As shown in FIG. 8, a second light-emitting unit 320 is prepared in a region where the second isolation opening 212 is located, and a second encapsulation portion 420 is prepared on a side of the second light-emitting unit 320 that faces away from the substrate 100, where the first encapsulation portion 410 and the second encapsulation portion 420 each include a first high-density layer 400a and a low-density layer 400b that are stacked, a film thickness of the low-density layer 400b of the first encapsulation portion 410 being less than a film thickness of the low-density layer 400b of the second encapsulation portion 420.

In this embodiment, the first light-emitting unit 310 and the second light-emitting unit 320 are prepared sequentially. During preparation of the first light-emitting unit 310, a sidewall 204 on a side of the isolation structure 200 that faces the second isolation opening 212 is etched, which increases the degree of recession on the side of the isolation structure 200 that faces the second isolation opening 212. During preparation of the second encapsulation portion 420, the thickness of the low-density layer 400b of the second encapsulation portion 420 is made greater than the thickness of the low-density layer 400b of the first encapsulation portion 410. A larger thickness of the second encapsulation portion 420 enables filling of at least part of the sidewall 204 on the side of the isolation structure 200 that faces the second isolation opening 212, to reduce the degree of recession of the second encapsulation portion 420, thereby improving the reliability of the second encapsulation portion 420.

In some embodiments, step S02 includes the following steps.

As shown in FIG. 9, a first light-emitting material layer 311 and a first encapsulation material layer 411 are sequentially formed in the isolation opening 210 and on the side of the isolation structure 200 that faces away from the substrate 100; and

as shown in FIG. 7, the first encapsulation material layer 411 and the first light-emitting material layer 311 in a region where the second isolation opening 212 is located are removed to form the first encapsulation portion 410 and the first light-emitting unit 310.

In these embodiments, the first light-emitting material layer 311 and the first encapsulation material layer 411 are formed sequentially, where the first encapsulation material layer 411 is located on a side of the first light-emitting material layer 311 that faces away from the substrate 100, and the first light-emitting material layer 311 and the first encapsulation material layer 411 cover the isolation opening 210 and the side of the isolation structure 200 that faces away from the substrate 100. That is, when the isolation opening 210 includes the first isolation opening 211 and the second isolation opening 212, the first light-emitting material layer 311 and the first encapsulation material layer 411 cover the first isolation opening 211 and the second isolation opening 212. The first encapsulation material layer 411 and the first light-emitting material layer 311 in the region where the second isolation opening 212 is located are removed to form the second light-emitting unit 320 and the second encapsulation portion 420. In the process of removing the first encapsulation material layer 411 and the first light-emitting material layer 311 in the region where the second isolation opening 212 is located, the sidewall 204 on the side of the isolation structure 200 that faces the second isolation opening 212 is etched, which increases the degree of recession of the sidewall 204 on the side of the isolation structure 200 that faces the second isolation opening 212. During formation of the second encapsulation portion 420, it is necessary to set the low-density layer 400b of the second encapsulation portion 420 to be thicker to better fill the sidewall 204 on the side of the isolation structure 200 that faces the second isolation opening 212, to reduce the degree of recession of the second encapsulation portion 420 when covering the sidewall 204 on the side of the isolation structure 200 that faces the second isolation opening 212, thereby improving the reliability of the second encapsulation portion 420.

In one embodiment, the first light-emitting material layer 311 in the region where the second isolation opening 212 is located is removed by using wet etching, which may allow for erosion of the first sub-layer 201 on the side of the isolation structure 200 that faces the second isolation opening 212, thereby increasing the degree of recession of the sidewall 204 on the side of the isolation structure 200 that faces the second isolation opening 212.

In one embodiment, as shown in FIG. 9, a first sub-electrode layer 351 is further formed between the first light-emitting material layer 311 and the first encapsulation material layer 411. The first sub-electrode layer 351 is simultaneously removed in the step of removing the first light-emitting material layer 311 in the region where the second isolation opening 212 is located by using wet etching, to form a second electrode 350 located within the first isolation opening 211.

As shown in FIG. 5, in some embodiments, after step S03, the method further includes the following step.

Step S04: As shown in FIG. 2, a third light-emitting unit 330 is prepared in a third isolation opening 213, and a third encapsulation portion 430 is prepared on a side of the third light-emitting unit 330 that faces away from the substrate 100, the film thickness of the low-density layer 400b of the first encapsulation portion 410 being less than a film thickness of the low-density layer 400b of the third encapsulation portion 430.

In these embodiments, the first light-emitting unit 310, the second light-emitting unit 320, and the third light-emitting unit 330 are prepared sequentially. During preparation of the first light-emitting unit 310, the sidewall 204 on a side of the isolation structure 200 that faces the second isolation opening 212 and the third isolation opening 213 is etched, which increases the degree of recession on the side of the isolation structure 200 that faces the second isolation opening 212 and the third isolation opening 213. During preparation of the second light-emitting unit 320, the sidewall 204 on a side of the isolation structure 200 that faces the third isolation opening 213 is further etched, which further increases the degree of recession on the side of the isolation structure 200 that faces the third isolation opening 213. During preparation of the low-density layer 400b of the third encapsulation portion 430, the thickness of the low-density layer 400b of the third encapsulation portion 430 is made greater than the thickness of the low-density layer 400b of the first encapsulation portion 410. A larger thickness of the low-density layer 400b of the third encapsulation portion 430 enables filling of at least part of the sidewall 204 on the side of the isolation structure 200 that faces the third isolation opening 213, to reduce the degree of recession of the third encapsulation portion 430, thereby improving the reliability of the third encapsulation portion 430.

In one embodiment, the film thickness of the low-density layer 400b of the second encapsulation portion 420 is less than the film thickness of the low-density layer 400b of the third encapsulation portion 430. Further, the film thickness of the low-density layer 400b of the third encapsulation portion 430 is made greater than the film thickness of the low-density layer 400b of the second encapsulation portion 420, thereby reducing the degree of recession of the third encapsulation portion 430.

In one embodiment, the step of removing the first encapsulation material layer 411 and the first light-emitting material layer 311 in a region where the second isolation opening 212 is located, to form the first encapsulation portion 410 and the first light-emitting unit 310 further includes: removing the first encapsulation material layer 411 and the first light-emitting material layer 311 in a region where the third isolation opening 213 is located, to form the first encapsulation portion 410 and the first light-emitting unit 310.

In one embodiment, step S03 further includes the following steps.

A second light-emitting material layer and a second encapsulation material layer are sequentially formed in the isolation opening 210 and on the side of the isolation structure 200 that faces away from the substrate 100; and
with reference to FIG. 8, the second encapsulation material layer and the second light-emitting material layer in a region where the first isolation opening 211 and the third isolation opening 213 are located are removed to form the second encapsulation portion 420 and the second light-emitting unit 320.

The second light-emitting material layer in the region where the third isolation opening 213 is located is wet-etched to erode the first sub-layer 201 on the side of the isolation structure 200 that faces the third isolation opening 213, thereby increasing the degree of recession of the sidewall 204 on the side of the isolation structure 200 that faces the third isolation opening 213.

In one embodiment, a second sub-electrode layer is further formed between the second light-emitting material layer and the second encapsulation material layer. The second sub-electrode layer is simultaneously removed in the step of removing the second light-emitting material layer in the region where the first isolation opening 211 and the third isolation opening 213 are located by using wet etching, to form a second electrode 350 located within the second isolation opening 212.

In one embodiment, step S04 includes the following steps.

A third light-emitting material layer and a third encapsulation material layer are sequentially formed in the isolation opening 210 and on the side of the isolation structure 200 that faces away from the substrate 100; and
with reference to FIG. 2, the third encapsulation material layer and the third light-emitting material layer in a region where the first isolation opening 211 and the second isolation opening 212 are located are removed to form the third encapsulation portion 430 and the third light-emitting unit 330.

In one embodiment, a third sub-electrode layer is further formed between the third light-emitting material layer and the third encapsulation material layer. The third sub-electrode layer is simultaneously removed in the step of removing the third light-emitting material layer in the region where the first isolation opening 211 and the second isolation opening 212 are located by using wet etching, to form a second electrode 350 located within the third isolation opening 213.

Although the present application is described with reference to the some embodiments, various modifications can be made, and equivalents can be provided to substitute for the components thereof without departing from the scope of the present application. In particular, the embodiments can be combined in any manner, provided that there is no structural conflict. The present application is not limited to the embodiments disclosed herein but includes all the embodiments that fall within the scope of the claims.

1. A display panel, comprising:
a substrate;
an isolation structure disposed on a side of the substrate, wherein the isolation structure encloses a plurality of isolation openings, the isolation openings comprising a plurality of first isolation openings and second isolation openings;
a light-emitting layer comprising a plurality of light-emitting units, the light-emitting at least partially located within the isolation opening; and
a first encapsulation layer comprising a plurality of encapsulation portions, the encapsulation portion configured to encapsulate the light-emitting unit, the encapsulation portion comprising a first high-density layer and a low-density layer that are stacked, and the encapsulation portion comprising a first encapsulation portion located within the first isolation opening and a second encapsulation portion located within the second isolation opening,
wherein a film thickness of the low-density layer of at least one first encapsulation portion is less than a film thickness of the low-density layer of the second encapsulation portion.

2. The display panel according to claim 1, wherein the isolation structure comprises a first sub-layer and a second sub-layer, the second sub-layer being located on a side of the first sub-layer that faces away from the substrate, and an orthographic projection of the first sub-layer on the substrate being within an orthographic projection of the second sub-layer on the substrate.

3. The display panel according to claim 2, wherein on a peripheral side of the first isolation opening, there is a first spacing between an edge of the orthographic projection of the first sub-layer on the substrate and an edge of the orthographic projection of the second sub-layer on the substrate; and on a peripheral side of the second isolation opening, there is a second spacing between an edge of the orthographic projection of the first sub-layer on the substrate and an edge of the orthographic projection of the second sub-layer on the substrate, the first spacing being less than or equal to the second spacing, wherein on the peripheral side of the first isolation opening, there is the first spacing between an edge of an orthographic projection, on the substrate, of a surface of the first sub-layer that faces the second sub-layer and the edge of the orthographic projection of the second sub-layer on the substrate; and
on the peripheral side of the second isolation opening, there is the second spacing between an edge of an orthographic projection, on the substrate, of a surface of the first sub-layer that faces the second sub-layer and the edge of the orthographic projection of the second sub-layer on the substrate.

4. The display panel according to claim 2, wherein the display panel further comprises a pixel define layer, the pixel define layer being located between the substrate and the isolation structure, and the pixel define layer comprising a plurality of pixel defining portions and a pixel opening enclosed by the pixel defining portion, the pixel opening being in communication with the isolation opening, wherein the light-emitting unit is located within the pixel opening; and the low-density layer comprises a first segment and a second segment that are connected to each other, an orthographic projection of the first segment on the substrate being within an orthographic projection of the pixel opening on the substrate, and the second segment covering a sidewall of the isolation structure that faces the isolation opening,
wherein a thickness of the first segment of the at least one first encapsulation portion is less than a thickness of the first segment of the second encapsulation portion in a thickness direction of the display panel;
or a thickness of the second segment of the at least one first encapsulation portion is less than a thickness of the second segment of the second encapsulation portion in a thickness direction perpendicular to the display panel.

5. The display panel according to claim 4, wherein the second segment has a side edge that faces away from a side of the isolation structure, and an orthographic projection of the side edge of the at least one encapsulation portion on the substrate is on a side of the orthographic projection of the second sub-layer on the substrate that faces the isolation opening.

6. The display panel according to claim 4, wherein the low-density layer further comprises a third segment connected to the second segment and located on a side of the isolation structure that faces away from the substrate, the third segment of each encapsulation portion being spaced apart from each other.

7. The display panel according to claim 6, wherein a thickness of the third segment of the first encapsulation portion is less than a thickness of the third segment of the second encapsulation portion in the thickness direction of the display panel.

8. The display panel according to claim 7, wherein the first segment or the third segment or both of the first encapsulation portion have a thickness of 950 nanometers to 1150 nanometers.

9. The display panel according to claim 7, wherein the first segment or the third segment or both of the second encapsulation portion have a thickness of 1250 nanometers to 1450 nanometers.

10. The display panel according to claim 7, wherein the isolation opening further comprises a third isolation opening, and the encapsulation portion comprises a third encapsulation portion located within the third isolation opening, wherein a film thickness of the low-density layer of at least one second encapsulation portion is less than a film thickness of the low-density layer of the third encapsulation portion.

11. The display panel according to claim 10, wherein on a peripheral side of the third isolation opening, there is a third spacing between an edge of the orthographic projection of the first sub-layer on the substrate and an edge of the orthographic projection of the second sub-layer on the substrate, the second spacing being less than or equal to the third spacing; wherein on the peripheral side of the third isolation opening, there is the third spacing between an edge of an orthographic projection, on the substrate, of a surface of the first sub-layer that faces the second sub-layer and the edge of the orthographic projection of the second sub-layer on the substrate.

12. The display panel according to claim 10, wherein a thickness of the first segment of the at least one second encapsulation portion is less than a thickness of the first segment of the third encapsulation portion in the thickness direction of the display panel;
or a thickness of the second segment of the at least one second encapsulation portion is less than a thickness of the second segment of the third encapsulation portion in the thickness direction perpendicular to the display panel.

13. The display panel according to claim 12, wherein a thickness of the third segment of the second encapsulation portion is less than a thickness of the third segment of the third encapsulation portion in the thickness direction of the display panel.

14. The display panel according to claim 10, wherein the light-emitting unit comprises a first light-emitting unit located within the first isolation opening, a second light-emitting unit located within the second isolation opening, and a third light-emitting unit located within the third isolation opening, the first light-emitting unit, the second light-emitting unit, and the third light-emitting unit emitting light of different colors.

15. The display panel according to claim 14, wherein the display panel further comprises a first electrode located on a side of the light-emitting unit that faces the substrate and a second electrode located on a side of the light-emitting unit that faces away from the substrate, the second electrode being located on a side of the encapsulation portion that faces the substrate.

16. The display panel according to claim 1, wherein the first high-density layer is disposed on a side of the low-density layer that faces away from the substrate;
or the low-density layer is disposed on a side of the first high-density layer that faces away from the substrate.

17. The display panel according to claim 1, wherein the low-density layer is disposed on a side of the first high-density layer that faces away from the substrate, and the encapsulation portion further comprises a second high-density layer disposed on a side of the low-density layer that faces away from the substrate,
wherein a silicon nitride content in a material of the low-density layer is less than a silicon nitride content in a material of the first high-density layer;
or a silicon nitride content in a material of the low-density layer is less than a silicon nitride content in a material of the second high-density layer.

18. A display panel, comprising:
a substrate;
an isolation structure disposed on a side of the substrate, wherein the isolation structure encloses a plurality of isolation openings, and the isolation structure comprises a first sub-layer and a second sub-layer, the second sub-layer being located on a side of the first sub-layer that faces away from the substrate, and the second sub-layer protruding toward the isolation opening by a spacing relative to the first sub-layer;
a light-emitting layer comprising a plurality of light-emitting units, the light-emitting unit at least partially located within the isolation opening; and
a first encapsulation layer comprising an encapsulation portion configured to encapsulate each light-emitting unit, wherein the encapsulation portion comprises a first high-density layer and a low-density layer that are stacked, a film thickness of the low-density layer of each encapsulation portion being linearly correlated with the corresponding spacing.

19. The display panel according to claim 18, wherein the isolation openings comprise a plurality of first isolation openings and second isolation openings, wherein on a peripheral side of the first isolation opening, the spacing comprises a first spacing by which the second sub-layer protrudes toward the isolation opening relative to the first sub-layer; and on a peripheral side of the second isolation opening, the spacing comprises a second spacing by which the second sub-layer protrudes toward the isolation opening relative to the first sub-layer, the first spacing being less than the second spacing; and the encapsulation portion comprises a first encapsulation portion located within the first isolation opening and a second encapsulation portion located within the second isolation opening,
wherein a film thickness of the low-density layer of at least one first encapsulation portion is less than a film thickness of the low-density layer of the second encapsulation portion.

20. A display apparatus, comprising:
a display panel, comprising:
a substrate;
an isolation structure disposed on a side of the substrate, wherein the isolation structure encloses a plurality of isolation openings, the isolation openings comprising a plurality of first isolation openings and second isolation openings;
a light-emitting layer comprising a plurality of light-emitting units, the light-emitting at least partially located within the isolation opening; and
a first encapsulation layer comprising a plurality of encapsulation portions, the encapsulation portion configured to encapsulate the light-emitting unit, the encapsulation portion comprising a first high-density layer and a low-density layer that are stacked, and the encapsulation portion comprising a first encapsulation portion located within the first isolation opening and a second encapsulation portion located within the second isolation opening,
wherein a film thickness of the low-density layer of at least one first encapsulation portion is less than a film thickness of the low-density layer of the second encapsulation portion;
or
a display panel, comprising:
a substrate;
an isolation structure disposed on a side of the substrate, wherein the isolation structure encloses a plurality of isolation openings, and the isolation structure comprises a first sub-layer and a second sub-layer, the second sub-layer being located on a side of the first sub-layer that faces away from the substrate, and the second sub-layer protruding toward the isolation opening by a spacing relative to the first sub-layer;
a light-emitting layer comprising a plurality of light-emitting units, the light-emitting unit at least partially located within the isolation opening; and
a first encapsulation layer comprising an encapsulation portion configured to encapsulate each light-emitting unit, wherein the encapsulation portion comprises a first high-density layer and a low-density layer that are stacked, a film thickness of the low-density layer of each encapsulation portion being linearly correlated with the corresponding spacing.
